(19) United States
(12) Patent Application Publication
(10) Pub. No.: US 2025/0286526 A1
(43) Pub. Date: Sep. 11, 2025

(54) FILTER HAVING STACKED STRUCTURE AND ELECTRIC PRODUCT INCLUDING THE SAME

(71) Applicant: LG INNOTEK CO., LTD., Seoul (KR)

(72) Inventors: Yu Seon KIM, Seoul (KR); Seok BAE, Seoul (KR)

(21) Appl. No.: 18/861,987

(22) PCT Filed: May 3, 2023
(86) PCT No.: PCT/KR2023/006048

§ 371 Date: Oct. 31, 2024

(30) Foreign Application Priority Data
May 4, 2022 (KR) 10-2022-0055603

(51) Int. Cl. H03H 1/00; H03H 7/01

(52) U.S. Cl. CPC H03H 1/00; H03H 7/0115; H03H 2001/0085

(57) ABSTRACT

A filter having a stacked structure of an embodiment comprises: a plurality of ground parts which are stacked in a first direction and have a plate shape; a plate-shaped signal part which is disposed to face the plurality of ground parts in the first direction between the plurality of ground parts; a linear signal part which is disposed to be adjacent to at least one of the plurality of ground parts or plate-shaped signal part in at least one direction of a second direction or a third direction; and a plurality of connection parts which extend in the first direction and electrically connect at least two of the plurality of ground parts, the plate-shaped signal part, and the linear signal part to each other, wherein the second direction intersects the first direction, and the third direction intersects each of the first and second directions.

### TECHNICAL FIELD

Embodiments relate to a filter having a stacked structure.

### BACKGROUND ART

When implementing a filter using multiple resonators, parasitic capacitance may occur due to a potential difference between grounds, which may deteriorate the matching of a filter. In addition, the size of the filter may increase due to separation between the grounds. In addition, the efficiency of an inductor included in the resonator may deteriorate due to the parasitic capacitance between the grounds. Therefore, the performance of the filter deteriorates for the various reasons mentioned above, and research is continuously conducted to improve the performance of the filter.

### DISCLOSURE

### Technical Problem

Embodiments provide a filter having a stacked structure having improved performance.

### Technical Solution

A filter having a stacked structure according to an embodiment may include a plurality of grounds stacked in a first direction, the plurality of grounds having a plate-like shape, a plate signal part disposed between the plurality of grounds while facing the plurality of grounds in the first direction, a line signal part disposed adjacent to at least one of the plurality of grounds or the plate signal part in at least one of a second direction or a third direction, and a plurality of connection parts extending in the first direction to conductively connect at least two of the plurality of grounds, the plate signal part, and the line signal part to each other. The second direction may intersect the first direction, and the third direction may intersect each of the first and second directions.

In an example, the plurality of grounds may include a bottom ground, a top ground disposed above the bottom ground in the first direction, a first inserted ground disposed adjacent to the top ground, a second inserted ground disposed adjacent to the bottom ground, a first separate ground disposed between the first inserted ground and the second inserted ground in the first direction, a third inserted ground disposed adjacent to the bottom ground and spaced apart from the second inserted ground in the second direction, a fourth inserted ground disposed adjacent to the top ground and spaced apart from the first inserted ground in the second direction, and a second separate ground disposed between the third inserted ground and the fourth inserted ground in the first direction. The first separate ground may be conductively connected to the first and second inserted grounds, and the second separate ground may be conductively connected to the third and fourth inserted grounds.

In an example, the plate signal part may include a first plate signal part spaced apart from each of the first inserted ground and the first separate ground in the first direction and disposed between the first inserted ground and the first separate ground, a second plate signal part spaced apart from each of the first separate ground and the second inserted ground in the first direction and disposed between the first separate ground and the second inserted ground, a third plate signal part spaced apart from each of the first plate signal part and the second plate signal part in the first direction and disposed between the first plate signal part and the second plate signal part, a fourth plate signal part spaced apart from each of the third inserted ground and the second separate ground in the first direction and disposed between the third inserted ground and the second separate ground, a fifth plate signal part spaced apart from each of the fourth inserted ground and the second separate ground in the first direction and disposed between the fourth inserted ground and the second separate ground, and a sixth plate signal part spaced apart from each of the fourth plate signal part and the fifth plate signal part in the first direction and disposed between the fourth plate signal part and the fifth plate signal part.

In an example, each of the first to sixth plate signal parts may be disposed so as to be spaced apart from a ground adjacent thereto in the first direction among the plurality of grounds, with a dielectric interposed therebetween.

In an example, the first separate ground may have a plane shape spaced apart from the third plate signal part while surrounding the third plate signal part.

In an example, the second separate ground may have a plane shape spaced apart from the sixth plate signal part while surrounding the sixth plate signal part.

In an example, the plurality of connection parts may include a first connection part extending in the first direction to connect the first plate signal part and the third plate signal part to each other and a second connection part extending in the first direction to connect the fifth plate signal part and the sixth plate signal part to each other.

In an example, the line signal part may include a first line signal part disposed in a bent line shape extending from the first plate signal part in at least one of the second direction or the third direction, a second line signal part disposed in a bent line shape extending from a point near the first separate ground in at least one of the second direction or the third direction, a third line signal part disposed in a bent line shape extending from the fourth plate signal part in at least one of the second direction or the third direction, and a fourth line signal part disposed in a bent line shape extending from the fifth plate signal part in at least one of the second direction or the third direction.

In an example, the plurality of connection parts may further include a third connection part extending in the first direction to connect the second line signal part and the second plate signal part to each other.

In an example, the plurality of connection parts may include a fourth connection part extending in the first direction to connect the first inserted ground, the first separate ground, and the second inserted ground to each of the top ground and the bottom ground, a fifth connection part extending in the first direction to connect the third inserted ground, the second separate ground, and the fourth inserted ground to each of the top ground and the bottom ground, a sixth connection part connecting the first line signal part to each of the top ground and the bottom ground, a seventh connection part connecting the second line signal part to each of the top ground and the bottom ground, an eighth connection part connecting the third line signal part to each of the top ground and the bottom ground, and a ninth connection part connecting the fourth line signal part to each of the top ground and the bottom ground.

In an example, the second inserted ground and the third inserted ground may be disposed on a first layer so as to be spaced apart from each other in the second direction. The second plate signal part, the fourth plate signal part, and the third line signal part may be disposed on a second layer located above the first layer in the first direction. The first and second separate grounds, which are spaced apart from each other in the second direction, the third and sixth plate signal parts, which are spaced apart from each other in the second direction, and the second line signal part may be disposed on a third layer located above the second layer in the first direction. The first and fifth plate signal parts, which are spaced apart from each other in the second direction, and the first and fourth line signal parts may be disposed on a fourth layer located above the third layer in the first direction. The first inserted ground and the fourth inserted ground may be disposed on a fifth layer located above the fourth layer in the first direction so as to be spaced apart from each other in the second direction.

In an example, the filter having a stacked structure may further include a plurality of fences having a strip pillar shape extending in the first direction, disposed adjacent to the first and fourth line signal parts, and conductively connecting the top ground and the bottom ground to each other.

In an example, the plurality of fences may include a first fence adjacent to the sixth connection part, a second fence adjacent to the ninth connection part, and intermediate fences arranged in the second direction while being spaced apart from each other between the first fence and the second fence.

In an example, the filter having a stacked structure according to the embodiment may have a transmission zero determined in accordance with a spacing distance between the first line signal part and the fourth line signal part and the number of the plurality of fences.

In an example, the first line signal part and the fourth line signal part may have plane shapes spaced apart from each other with at least some of the plurality of fences interposed therebetween.

In an example, the plurality of grounds, the plate signal part, and the line signal part may form a plurality of resonators that are separate from each other. The plurality of resonators may include a first resonator including the first inserted ground, the first plate signal part, the third plate signal part, the first separate ground, and the first line signal part, a second resonator including the first separate ground, the second plate signal part, the third plate signal part, the second inserted ground, and the second line signal part, a third resonator including the second separate ground, the fourth plate signal part, the sixth plate signal part, the third inserted ground, and the third line signal part, and a fourth resonator including the fourth inserted ground, the fifth plate signal part, the sixth plate signal part, the second separate ground, and the fourth line signal part.

In an example, the filter having a stacked structure may further include a first input/output port extending and protruding outward from one side of the first line signal part connected to the first plate signal part and a second input/output port extending and protruding outward from one side of the fourth line signal part connected to the fifth plate signal part.

In an example, the filter having a stacked structure may further include a dielectric in which the plurality of grounds, the plate signal part, the line signal part, and the plurality of connection parts are embedded.

A filter having a stacked structure according to another embodiment may include top and bottom grounds disposed opposite each other while being vertically spaced apart from each other, a separate ground disposed between the top ground and the bottom ground, a plurality of signal parts disposed between the separate ground and each of the top ground and the bottom ground to form a resonator, and a connection part connecting the separate ground and the plurality of signal parts to each of the top ground and the bottom ground.

### Advantageous Effects

A filter having a stacked structure according to the embodiment may have a compact configuration and low insertion loss, and may exhibit excellent performance in that the center frequency and the bandwidth thereof are easily adjusted and, particularly, the transmission zero thereof is accurately adjusted, and the order thereof may be increased, whereby the embodiment may be easily applied to a filter having various functions and thus may have a wide application range.

### DESCRIPTION OF DRAWINGS

FIG. 1 illustrates an exploded perspective view of the external appearance of a filter according to an embodiment.

FIG. 2 illustrates a coupled perspective view of the external appearance of the filter shown in FIG. 1.

FIG. 3 illustrates a front view of the filter shown in FIG. 1.

FIG. 4A illustrates a bottom view of a fifth layer in the filter shown in FIGS. 1 and 3.

FIG. 4B illustrates a plan view of first to fourth layers in the filter shown in FIGS. 1 and 3, with only the fifth layer removed therefrom.

FIG. 4C illustrates a plan view of the first to third layers in the filter shown in FIGS. 1 and 3, with the fourth layer and the fifth layer removed therefrom.

FIG. 4D illustrates a plan view of the first and second layers in the filter shown in FIGS. 1 and 3, with the third to fifth layers removed therefrom.

FIG. 4E illustrates a plan view of only the first layer in the filter shown in FIGS. 1 and 3, with the second to fifth layers removed therefrom.

FIG. 5 illustrates an equivalent circuit of the filter shown in FIG. 1.

FIG. 6 is a graph for explaining the characteristics of the filter according to the embodiment.

### BEST MODE

Hereinafter, the present disclosure will be described more fully hereinafter with reference to the accompanying drawings, in which various embodiments are shown. The examples, however, may be embodied in many different forms, and should not be construed as being limited to the embodiments set forth herein. Rather, these embodiments are provided so that this disclosure will be more thorough and complete, and will more fully convey the scope of the disclosure to those skilled in the art.

It will be understood that when an element is referred to as being “on” or “under” another element, it may be directly on/under the element, or one or more intervening elements may also be present.

In addition, when an element is referred to as being “on” or “under”, “under the element” as well as “on the element” may be included based on the element.

In addition, relational terms, such as “first”, “second”, “on/upper part/above”, and “under/lower part/below”, are used only to distinguish between one subject or element and another subject or element, without necessarily requiring or involving any physical or logical relationship or sequence between the subjects or elements.

Hereinafter, a filter having a stacked structure (hereinafter referred to as a “filter”) according to an embodiment will be described with reference to the accompanying drawings. Although the filter will be described using the Cartesian coordinate system (x-axis, y-axis, and z-axis) for convenience of description, the filter may also be described using other coordinate systems. For convenience of description, the x-axis direction will be referred to as a third direction, the y-axis direction will be referred to as a first direction, and the z-axis direction will be referred to as a second direction. For example, when the first direction corresponds to a vertical direction, at least one of the second direction or the third direction, which intersect the first direction, may correspond to a horizontal direction.

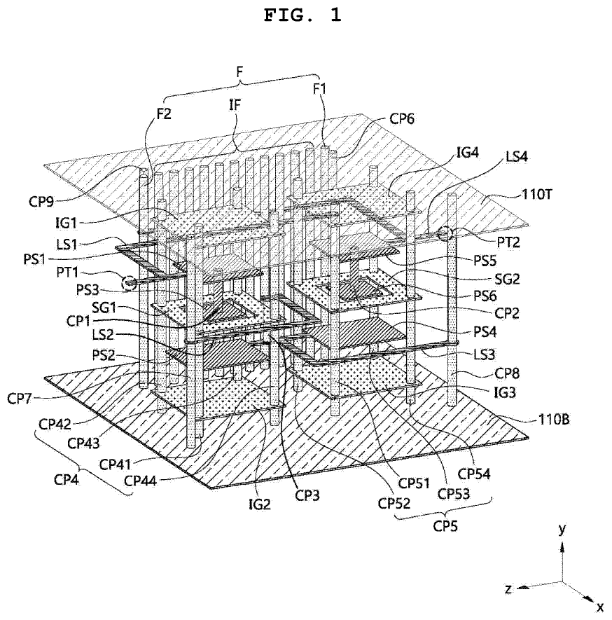

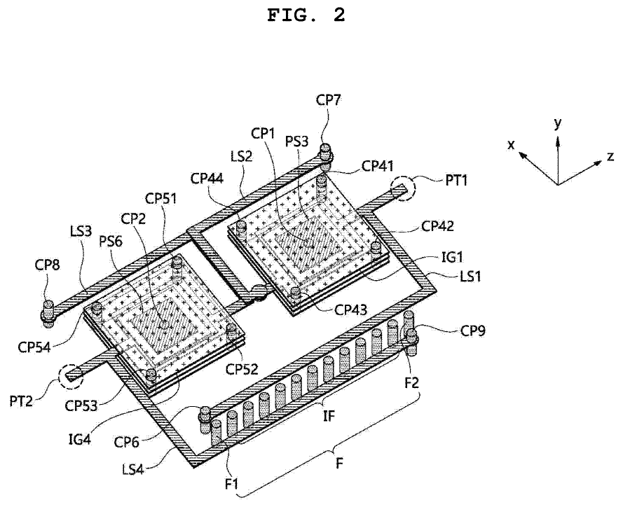

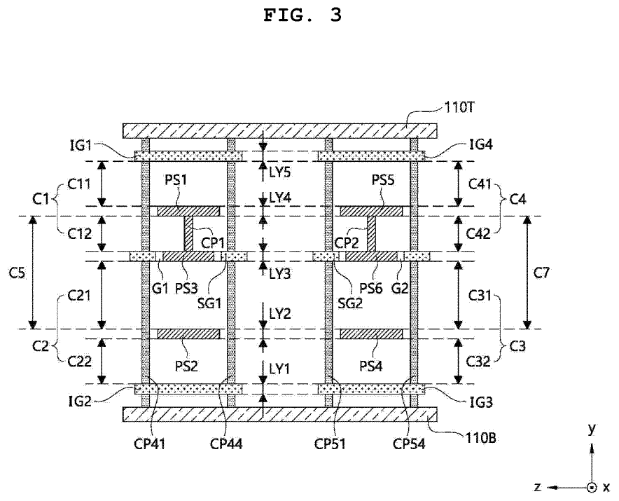

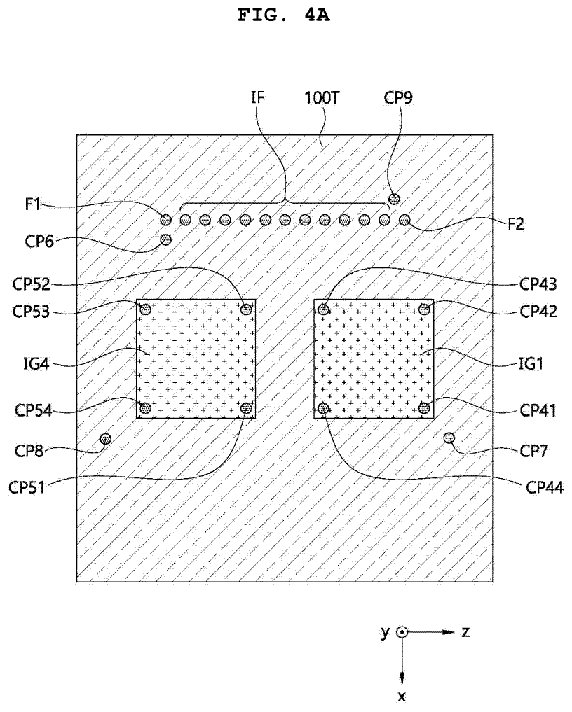

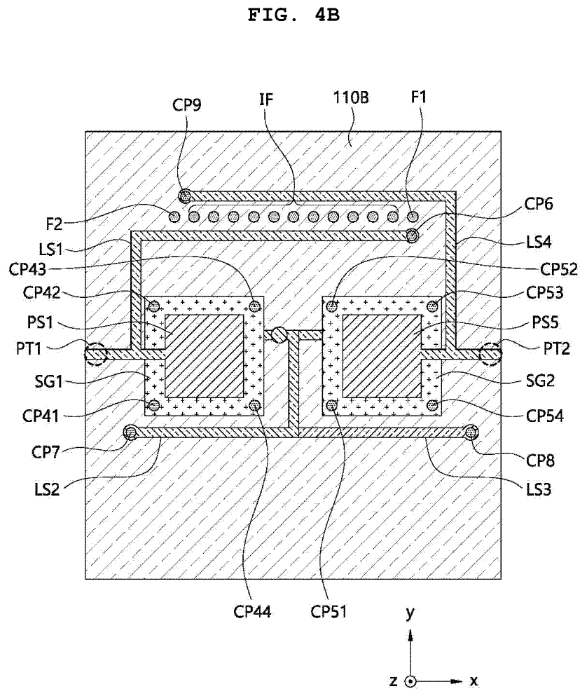

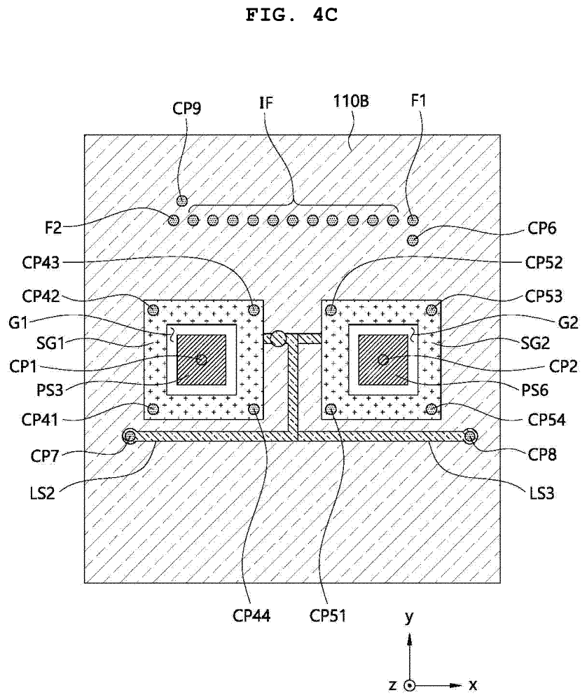

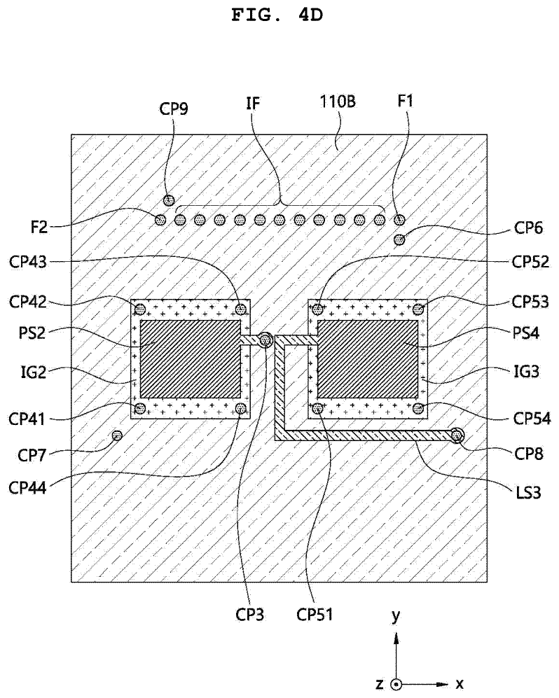

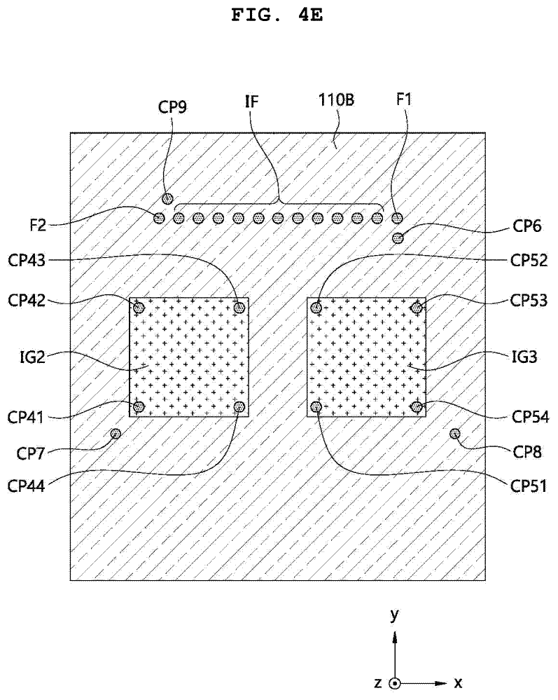

FIG. 1 illustrates an exploded perspective view of the external appearance of a filter according to an embodiment, FIG. 2 illustrates a coupled perspective view of the external appearance of the filter shown in FIG. 1, FIG. 3 illustrates a front view of the filter shown in FIG. 1, FIG. 4A illustrates a bottom view of a fifth layer in the filter shown in FIGS. 1 and 3, FIG. 4B illustrates a plan view of first to fourth layers in the filter shown in FIGS. 1 and 3, with only the fifth layer removed therefrom, FIG. 4C illustrates a plan view of the first to third layers in the filter shown in FIGS. 1 and 3, with the fourth layer and the fifth layer removed therefrom, FIG. 4D illustrates a plan view of the first and second layers in the filter shown in FIGS. 1 and 3, with the third to fifth layers removed therefrom, and FIG. 4E illustrates a plan view of only the first layer in the filter shown in FIGS. 1 and 3, with the second to fifth layers removed therefrom. For convenience of description, illustration of first to fourth line signal parts LS1 to LS4 shown in FIG. 1 is omitted from FIG. 3.

The filter according to the embodiment may include a top ground 110T, a bottom ground 110B, separate grounds SG (SG1 and SG2), a plurality of signal parts, and a connection part.

The top ground 110T and the bottom ground 110B may be disposed opposite each other while being spaced apart from each other in the vertical direction.

The separate grounds SG1 and SG2 may be disposed between the top ground 110T and the bottom ground 110B.

The plurality of signal parts may be disposed between the separate grounds SG1 and SG2 and each of the top ground 110T and the bottom ground 110B to form a capacitor and an inductor included in a resonator of the filter.

The connection part serves to connect the separate grounds SG1 and SG2 and the plurality of signal parts to the top ground 110T and the bottom ground 110B.

The configuration of the filter according to the embodiment will be described in more detail below.

The filter may include a plurality of grounds, a plate signal part PS, a line signal part LS, and a plurality of connection parts.

The plurality of grounds may be stacked in the first direction, and each of the plurality of grounds may have a plate-like shape, may be conductive, and may be made of metal.

The plurality of grounds may include a bottom ground 110B, a top ground 110T, first and second separate grounds SG1 and SG2, and first to fourth inserted grounds IG (IG1, IG2, IG3, and IG4).

The top ground 110T may be disposed above the bottom ground 110B in the first direction. For example, the top ground 110T may overlap the bottom ground 110B in the first direction.

The first inserted ground IG1 may be disposed adjacent to the top ground 110T, and the second inserted ground IG2 may be disposed adjacent to the bottom ground 110B.

The first separate ground SG1 is disposed between the first inserted ground IG1 and the second inserted ground IG2 in the first direction. The first separate ground SG1 serves to divide a space between the top ground 110T and the bottom ground 110B in the first direction. For example, a first distance by which the first separate ground SG1 is spaced apart from the top ground 110T in the first direction and a second distance by which the first separate ground SG1 is spaced apart from the bottom ground 110B in the first direction may be identical to each other, but the embodiments are not limited thereto. That is, as will be described later, the first and second distances may be determined so that the capacitor included in the resonator has desired capacitance.

The third inserted ground IG3 may be disposed adjacent to the bottom ground 110B and spaced apart from the second inserted ground IG2 in the second direction.

The fourth inserted ground IG4 may be disposed adjacent to the top ground 110T and spaced apart from the first inserted ground IG1 in the second direction.

The second separate ground SG2 may be disposed between the third inserted ground IG3 and the fourth inserted ground IG4 in the first direction. The second separate ground SG2 may be disposed so as to be spaced apart from the first separate ground SG1 in the second direction. Similar to the first separate ground SG1, the second separate ground SG2 serves to divide the space between the top ground 110T and the bottom ground 110B in the first direction. For example, a third distance by which the second separate ground SG2 is spaced apart from the top ground 110T in the first direction and a fourth distance by which the second separate ground SG2 is spaced apart from the bottom ground 110B in the first direction may be identical to each other, but the embodiments are not limited thereto. That is, as will be described later, the third and fourth distances may be determined so that the capacitor included in the resonator has desired capacitance.

As will be described later, the first separate ground SG1 may be conductively connected to each of the first and second inserted grounds IG1 and IG2 via the connection part, and the second separate ground SG2 may be conductively connected to each of the third and fourth inserted grounds IG3 and IG4 via the connection part.

Meanwhile, the plate signal part may be disposed between the plurality of grounds, may be disposed so as to face the plurality of grounds in the first direction, and may be conductive. For example, the plate signal part may be made of metal.

The plate signal part may include first to sixth plate signal parts PS1 to PS6.

The first plate signal part PS1 may be spaced apart from each of the first inserted ground IG1 and the first separate ground SG1 in the first direction, and may be disposed between the first inserted ground IG1 and the first separate ground SG1.

The second plate signal part PS2 may be spaced apart from each of the first separate ground SG1 and the second inserted ground IG2 in the first direction, and may be disposed between the first separate ground SG1 and the second inserted ground IG2.

The third plate signal part PS3 may be spaced apart from each of the first plate signal part PS1 and the second plate signal part PS2 in the first direction, and may be disposed between the first plate signal part PS1 and the second plate signal part PS2.

The fourth plate signal part PS4 may be spaced apart from each of the third inserted ground IG3 and the second separate ground SG2 in the first direction, and may be disposed between the third inserted ground IG3 and the second separate ground SG2.

The fifth plate signal part PS5 may be spaced apart from each of the fourth inserted ground IG4 and the second separate ground SG2 in the first direction, and may be disposed between the fourth inserted ground IG4 and the second separate ground SG2.

The sixth plate signal part PS6 may be spaced apart from each of the fourth plate signal part PS4 and the fifth plate signal part PS5 in the first direction, and may be disposed between the fourth plate signal part PS4 and the fifth plate signal part PS5.

In this case, each of the first to sixth plate signal parts PS1 to PS6 may be disposed so as to be spaced apart from a corresponding ground adjacent thereto in the first direction among the plurality of grounds, with a dielectric interposed therebetween. The reason for this is to form the capacitor of the resonator, which will be described later.

According to the embodiment, the first separate ground SG1 may have a plane shape spaced apart from the third plate signal part PS3 while surrounding the same. For example, referring to FIGS. 3 and 4C, a gap (hereinafter referred to as a “first gap”) G1 may be formed between the first separate ground SG1 and the third plate signal part PS3. A dielectric may be disposed in the first gap G1.

In addition, the second separate ground SG2 may have a plane shape spaced apart from the sixth plate signal part PS6 while surrounding the same. To this end, referring to FIGS. 3 and 4C, a gap (hereinafter referred to as a “second gap”) G1 may be formed between the second separate ground SG2 and the sixth plate signal part PS6. A dielectric may be disposed in the second gap G2.

Meanwhile, the line signal part LS may be disposed adjacent to at least one of the plurality of grounds or the plate signal part in at least one of the second direction or the third direction, and may be made of a conductive material. For example, the line signal part may be made of metal.

For example, the line signal part may include first to fourth line signal parts LS1 to LS4.

The first line signal part LS1 may be disposed in a bent line shape extending from the first plate signal part PS1 in at least one of the second direction or the third direction. According to the embodiment, as shown in the drawings, the first line signal part LS1 may have a bent line shape extending from the first plate signal part PS1 in the second direction and the third direction.

The second line signal part LS2 may be disposed in a bent line shape extending from a point near the first separate ground SG1 in at least one of the second direction or the third direction. According to the embodiment, as shown in the drawings, the second line signal part LS2 may have a bent line shape extending from a point near the first separate ground SG1 in the second direction and the third direction.

The third line signal part LS3 may be disposed in a bent line shape extending from the fourth plate signal part PS4 in at least one of the second direction or the third direction. According to the embodiment, as shown in the drawings, the third line signal part LS3 may have a bent line shape extending from the fourth plate signal part PS4 in the second direction and the third direction.

The fourth line signal part LS4 may be disposed in a bent line shape extending from the fifth plate signal part PS5 in at least one of the second direction or the third direction. According to the embodiment, as shown in the drawings, the fourth line signal part LS4 may have a bent line shape extending from the fifth plate signal part PS5 in the second direction and the third direction.

Meanwhile, the plurality of connection parts CP extend in the first direction to conductively connect at least two of the plurality of grounds, the plate signal part, and the line signal part to each other. To this end, the plurality of connection parts may be made of a conductive metal.

According to the embodiment, the plurality of connection parts may include first to ninth connection parts CP1 to CP9.

The first connection part CP1 may extend in the first direction to conductively connect the first plate signal part PS1 and the third plate signal part PS3 to each other. Accordingly, the first plate signal part PSI and the third plate signal part PS3 may be connected to each other via the first connection part CP1 to form an equipotential therebetween.

The second connection part CP2 may extend in the first direction to conductively connect the fifth plate signal part PS5 and the sixth plate signal part PS6 to each other. Accordingly, the fifth plate signal part PS5 and the sixth plate signal part PS6 may be connected to each other via the second connection part CP2 to form an equipotential therebetween.

The third connection part CP3 may extend in the first direction to conductively connect the second line signal part LS2 and the second plate signal part PS2 to each other.

The fourth connection part CP4 may extend in the first direction to conductively connect the first inserted ground IG1, the first separate ground SG1, and the second inserted ground IG2 to each of the top ground 110T and the bottom ground 110B. TO this end, the fourth connection part CP4 may include 4-1^{st} to 4-4^{th} connection parts CP41, CP42, CP43, and CP44 that conductively connect four corners of each of the first inserted ground IG1, the first separate ground SG1, and the second inserted ground IG2 to each of the top ground 110T and the bottom ground 110B.

The fifth connection part CP5 may extend in the first direction to conductively connect the third inserted ground IG3, the second separate ground SG2, and the fourth inserted ground IG4 to each of the top ground 110T and the bottom ground 110B. To this end, the fifth connection part CP5 may include 5-1^{st} to 5-4^{th} connection parts CP51, CP 52, CP 53, and CP 54 that conductively connect four corners of each of the third inserted ground IG3, the second separate ground SG2, and the fourth inserted ground IG4 to each of the top ground 110T and the bottom ground 110B.

The sixth connection part CP6 may conductively connect the first line signal part LS1 to each of the top ground 110T and the bottom ground 110B.

The seventh connection part CP7 may conductively connect the second line signal part LS2 to each of the top ground 110T and the bottom ground 110B.

The eighth connection part CP8 may conductively connect the third line signal part LS3 to each of the top ground 110T and the bottom ground 110B.

The ninth connection part CP9 may conductively connect the fourth line signal part LS4 to each of the top ground 110T and the bottom ground 110B.

Meanwhile, the filter according to the embodiment may further include a plurality of fences F.

The plurality of fences F may have a strip pillar shape that extends in the first direction, is disposed adjacent to the first line signal part LS1 and the fourth line signal part LS4, and conductively connects the top ground 110T and the bottom ground 110B to each other. The plurality of fences F may be conductive and may be made of metal.

The plurality of fences F may include first, second, and intermediate fences F1, F2, and IF. The first fence F1 may be adjacent to the sixth connection part CP6, the second fence F2 may be adjacent to the ninth connection part CP9, and the intermediate fences IF may be arranged in the second direction while being spaced apart from each other between the first fence F1 and the second fence F2.

As illustrated, the number of the plurality of fences F may be 13. However, unlike what is illustrated, the number of the plurality of fences may be greater or less than 13.

The transmission zero of the filter according to the embodiment may be determined in accordance with the spacing distance between the first line signal part LS1 and the fourth line signal part LS4 and the number of the plurality of fences F. This will be described in detail later.

Referring to FIG. 4B, the first line signal part LS1 and the fourth line signal part LS4 may have plane shapes spaced apart from each other with at least some of the plurality of fences F interposed therebetween.

Meanwhile, as shown in FIG. 3, the filter according to the embodiment may have a multilayer structure, e.g., a five-layer structure.

The multiple layers will be sequentially referred to as a first layer LY1 to a fifth layer LY5 from the bottom to the top in the first direction. That is, the second layer LY2 is located above the first layer LY1 in the first direction, the third layer LY3 is located above the second layer LY2 in the first direction, the fourth layer LY4 is located above the third layer LY3 in the first direction, and the fifth layer LY5 is located above the fourth layer LY4 in the first direction.

The second inserted ground IG2 and the third inserted ground IG3 are disposed on the first layer LY1 so as to be spaced apart from each other in the second direction.

The second and fourth plate signal parts PS2 and PS4, which are spaced apart from each other in the second direction, and the third line signal part LS3 are disposed on the second layer LY2.

The first and second separate grounds SG1 and SG2, which are spaced apart from each other in the second direction, the third and sixth plate signal parts PS3 and PS6, which are spaced apart from each other in the second direction, and the second line signal part LS2 are disposed on the third layer LY3.

The first and fifth plate signal parts PS1 and PS5, which are spaced apart from each other in the second direction, and the first and fourth line signal parts LS1 and LS4 are disposed on the fourth layer LY4.

The first inserted ground IG1 and the fourth inserted ground IG4 are disposed on the fifth layer LY5 so as to be spaced apart from each other in the second direction.

The filter according to an embodiment may include at least one unit module, and the unit module may include a plurality of resonators. That is, the plurality of grounds, the plate signal part, and the line signal part described above may form a plurality of resonators that are separate from each other. One unit module may be configured as shown in FIG. 1.

A filter according to another embodiment may include a plurality of unit modules arranged in at least one of the first to third directions, and each of the plurality of unit modules may be configured as shown in FIG. 1.

The plurality of resonators may include first to fourth resonators.

The first resonator may include the first inserted ground IG1, the first plate signal part PS1, the third plate signal part PS3, the first separate ground SG1, and the first line signal part LS1.

The second resonator may include the first separate ground SG1, the second plate signal part PS2, the third plate signal part PS3, the second inserted ground IG2, and the second line signal part LS2. In addition, the third connection part CP3 may be included in the second resonator.

The third resonator may include the second separate ground SG2, the fourth plate signal part PS4, the sixth plate signal part PS6, the third inserted ground IG3, and the third line signal part LS3.

The fourth resonator may include the fourth inserted ground IG4, the fifth plate signal part PS5, the sixth plate signal part PS6, the second separate ground SG2, and the fourth line signal part LS4.

The filter according to the embodiment may include a dielectric. The plurality of grounds, the plate signal part, the line signal part, and the plurality of connection parts may be embedded in the dielectric. Therefore, in FIGS. 1 to 4E, the background color portion between the plurality of grounds, the plate signal part, the line signal part, and the plurality of connection parts may correspond to the dielectric.

In particular, as described above, in order to implement capacitors included in the first to fourth resonators with the structure shown in FIG. 1, the dielectric may be disposed between portions of the plurality of grounds and the plate signal part that face each other. In this case, the plurality of connection parts and the plurality of fences may be embedded in the dielectric in the form of vias. In this case, the vias may be stacked vias rather than through-vias.

For example, the dielectric may be manufactured using a low temperature co-fired ceramics (LTCC) method.

Hereinafter, the operation of the filter according to the above-described embodiment will be described with reference to the accompanying drawings.

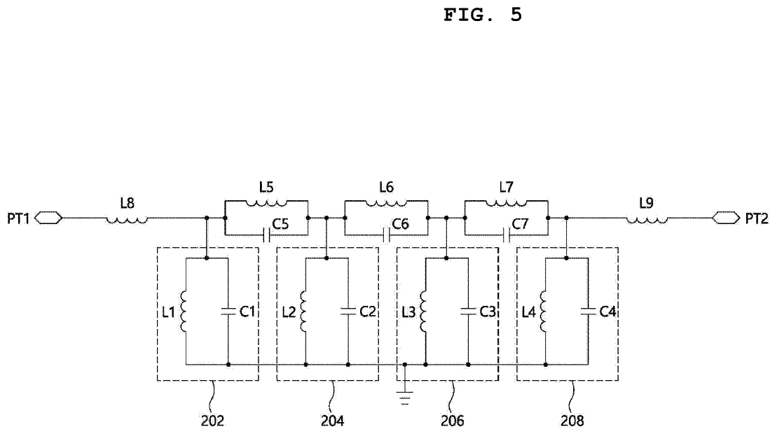

FIG. 5 illustrates an equivalent circuit of the filter shown in FIG. 1.

Although the capacitor or the inductor included in the resonator shown in FIG. 1 is a distributed constant circuit, the same will be interpreted as a lumped constant circuit in FIG. 5 in order to assist in understanding of the operation of the filter shown in FIG. 1.

The filter shown in FIG. 5 may include first to fourth resonators 202, 204, 206, and 208.

The first resonator 202 may include a first inductor L1 and a first capacitor C1, the second resonator 204 may include a second inductor L2 and a second capacitor C2, the third resonator 206 may include a third inductor L3 and a third capacitor C3, and the fourth resonator 208 may include a fourth inductor L4 and a fourth capacitor C4.

In addition, the filter shown in FIG. 5 may further include fifth to seventh capacitors C5, C6, and C7 and fifth to ninth inductors L5, L6, L7, L8, and L9.

In addition, the filter shown in FIG. 5 may further include first and second input/output ports PT1 and PT2. For example, the first input/output port PT1 may correspond to an input terminal of the filter, and the second input/output port PT2 may correspond to an output terminal of the filter. Alternatively, the first input/output port PT1 may correspond to an output terminal of the filter, and the second input/output port PT2 may correspond to an input terminal of the filter.

First, the first to seventh capacitors C1, C2, C3, C4, C5, C6, and C7 included in the resonators 202, 204, 206, and 208 will be described below with reference to FIGS. 1 and 3.

The first inserted ground IG1 and the first plate signal part PS1 may face each other with the dielectric interposed therebetween to form a 1-1^{st} capacitor C11, and the first plate signal part PS1 and the first separate ground SG1 may face each other with the dielectric interposed therebetween to form a 1-2^{nd} capacitor C12. In this case, the first capacitor C1 shown in FIG. 3 may include a capacitance component of each of the 1-1^{st} and 1-2^{nd} capacitors C11 and C12. For example, the first capacitor C1 shown in FIG. 5 may correspond to the first capacitor C1 shown in FIG. 3, but the embodiments are not limited thereto. That is, the first capacitor C1 shown in FIG. 5 may also include a capacitance component formed by the third plate signal part PS3 and the first separate ground SG1 facing each other with the dielectric interposed therebetween.

The first separate ground SG1 and the second plate signal part PS2 may face each other with the dielectric interposed therebetween to form a 2-1^{st} capacitor C21, and the second plate signal part PS2 and the second inserted ground IG2 may face each other with the dielectric interposed therebetween to form a 2-2^{nd} capacitor C22. In this case, the second capacitor C2 shown in FIG. 3 may include a capacitance component of each of the 2-1^{st} and 2-2^{nd} capacitors C21 and C22. For example, the second capacitor C2 shown in FIG. 5 may correspond to the second capacitor C2 shown in FIG. 3, but the embodiments are not limited thereto. That is, the second capacitor C2 shown in FIG. 5 may also include a capacitance component formed by the third plate signal part PS3 and the first separate ground SG1 facing each other with the dielectric interposed therebetween.

The second separate ground SG2 and the fourth plate signal part PS4 may face each other with the dielectric interposed therebetween to form a 3-1^{st} capacitor C31, and the fourth plate signal part PS4 and the third inserted ground IG3 may face each other with the dielectric interposed therebetween to form a 3-2^{nd} capacitor C32. In this case, the third capacitor C2 shown in FIG. 3 may include a capacitance component of each of the 3-1^{st} and 3-2^{nd} capacitors C31 and C32. For example, the third capacitor C3 shown in FIG. 5 may correspond to the third capacitor C3 shown in FIG. 3, but the embodiments are not limited thereto. That is, the third capacitor C3 shown in FIG. 5 may also include a capacitance component formed by the sixth plate signal part PS6 and the second separate ground SG2 facing each other with the dielectric interposed therebetween.

The fourth inserted ground IG4 and the fifth plate signal part PS5 may face each other with the dielectric interposed therebetween to form a 4-1^{st} capacitor C41, and the fifth plate signal part PS5 and the second separate ground SG2 may face each other with the dielectric interposed therebetween to form a 4-2^{nd} capacitor C42. In this case, the fourth capacitor C4 shown in FIG. 3 may include a capacitance component of each of the 4-1^{st} and 4-2^{nd} capacitors C41 and C42. For example, the fourth capacitor C4 shown in FIG. 5 may correspond to the fourth capacitor C4 shown in FIG. 3, but the embodiments are not limited thereto. That is, the fourth capacitor C4 shown in FIG. 5 may also include a capacitance component formed by the sixth plate signal part PS6 and the second separate ground SG2 facing each other with the dielectric interposed therebetween.

In addition, the fifth capacitor C5 shown in FIG. 5 may be formed by multi-coupling between the first capacitor C1 and the second capacitor C2 shown in FIG. 3, i.e., electrical coupling therebetween. For example, the fifth capacitor C5 formed by the first plate signal part PAL and the second plate signal part PA2 shown in FIG. 3, which face each other in the first direction, may correspond to the fifth capacitor C5 shown in FIG. 5.

The parasitic capacitance between the second line signal part LS2 and the third line signal part LS3 shown in FIG. 1 may be equivalent to the sixth capacitor C6 shown in FIG. 5. That is, the capacitance of the sixth capacitor C6 may be formed by a potential difference between the second line signal part LS2 and the third line signal part LS3. The internal parasitic capacitance component of the second line signal part LS2 is included in the second capacitor C2, and the internal parasitic capacitance component of the third line signal part LS3 is included in the third capacitor C3. Each of the second and third line signal parts LS2 and LS3 mainly has an inductance component, but also has a capacitance component. The sixth capacitor C6 may be implemented by this capacitance component, and the capacitance component of the sixth capacitor C6 is very small. In this way, the filter according to the embodiment may be used in the resonator without removing the parasitic capacitor component.

The seventh capacitor C7 shown in FIG. 5 may be formed by multi-coupling between the third capacitor C3 and the fourth capacitor C4 shown in FIG. 3, i.e., electrical coupling therebetween. For example, the seventh capacitor C7 formed by the fifth plate signal part PAS and the fourth plate signal part PA4 shown in FIG. 3, which face each other in the first direction, may correspond to the seventh capacitor C7 shown in FIG. 5.

In addition, the first to ninth inductors L1, L2, L3, L4, L5, L6, L7, L8, and L9 included in the resonators 202, 204, 206, and 208 will be described below with reference to FIG. 1.

The first inductor L1 shown in FIG. 5 may be implemented by shorting an end of the first line signal part LS1 disposed on the fourth layer LY4 together with the first plate signal part PS1 shown in FIG. 1.

In addition, the second inductor L2 shown in FIG. 5 may be implemented by shorting the second line signal part LS2. In this case, the third connection part CP3 connecting the second line signal part LS2 to the second plate signal part PS2 may implement the second inductor L2.

The third inductor L3 shown in FIG. 5 may be implemented by shorting an end of the third line signal part LS3 disposed on the second layer LY2 together with the fourth plate signal part PS4.

The fourth inductor L4 shown in FIG. 5 may be implemented by shorting an end of the fourth line signal part LS4 disposed on the fourth layer LY4 together with the fifth plate signal part PS5.

The fifth inductor L5 may be implemented as a parasitic value of the fifth capacitor C5, and the seventh inductor L7 may be implemented as a parasitic value of the seventh capacitor C7. The fifth and seventh inductors L5 and L7 may be implemented as mutual inductance due to magnetic coupling by parasitic inductance components included in the fifth and seventh capacitors C5 and C7, and may have very small values.

The sixth inductor L6 may be implemented as mutual inductance due to magnetic coupling between the second line signal part LS2 and the third line signal part LS3. That is, the inductance coupling between the second resonator 204 and the third resonator 206 may be reflected in the sixth inductor L6.

Referring again to FIGS. 1 and 5, the eighth inductor L8 has an inductance component present between the first input/output port PT1 and the first line signal part LS1, and the ninth inductor L9 has an inductance component present between the second input/output port PT2 and the fourth line signal part LS4.

For example, as shown in FIGS. 1 and 2, the first input/output port PT1 may have a protruding shape extending outward from one side of the first line signal part LS1 connected to the first plate signal part PS1, and the second input/output port PT2 may have a protruding shape extending outward from one side of the fourth line signal part LS4 connected to the fifth plate signal part PS5. However, the embodiments are not limited to any specific positions of the first and second input/output ports PT1 and PT2.

Hereinafter, a filter according to a comparative example and the filter according to the embodiment will be described with reference to the accompanying drawings.

The filter according to the comparative example is not provided with the top ground 110T, and has an open top. Thus, noise generated inside the filter is radiated to the outside. In contrast, in the case of the filter according to the embodiment, noise inside the filter may be removed through the ground.

A filter according to an embodiment may include only one unit module shown in FIG. 1. In this case, since the number of resonators 202, 204, 206, and 208 is four, the filter according to the embodiment is a fourth-order filter.

In a filter according to another embodiment, the unit module shown in FIG. 1 may include a plurality of unit modules arranged in an array form in at least one of the first direction, the second direction, or the third direction. In this case, the order of the filter according to the embodiment may be increased to ten to twenty. In this way, since the filter according to the embodiment has a stacked structure, the filter may be implemented as a multi-order filter, and thus may be used as a surface acoustic wave (SAW) filter and a BAR commercial filter.

In the case of the comparative example, the size of the filter increases due to separation between grounds. In contrast, in the case of the embodiment, since the grounds are inserted into the structure, that is, since the first and second separate grounds SG1 and SG2 are disposed on the third layer LY3 among the five layers LY1 to LY5, the size of the filter may be reduced compared to the comparative example.

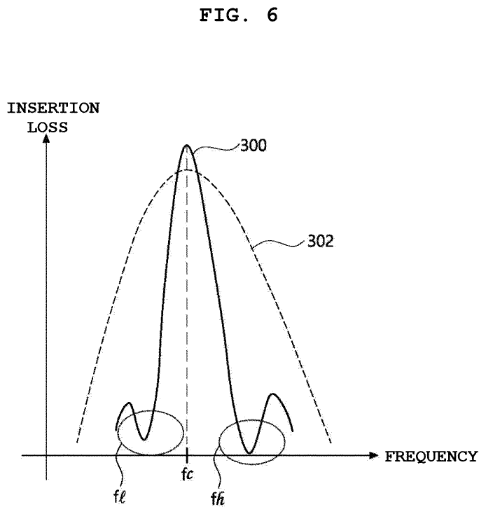

FIG. 6 is a graph for explaining the characteristics of the filter according to the embodiment, in which the horizontal axis represents frequency and the vertical axis represents insertion loss. Here, reference numeral 302 represents the characteristics of the filter according to the comparative example, and reference numeral 300 represents the characteristics of the filter according to the embodiment.

The filters according to the comparative example and the embodiment are bandpass filters.

A reverse mutual inductance component −M is present between the first line signal part LS1 and the fourth line signal part LS4, and cross-coupling is provided between the first line signal part LS1 and the fourth line signal part LS4 to set the stopband of the filter to a desired level.

As the mutual inductance M increases, the transmission zeros f1 and fh approach the passband. The coupling degree may be precisely controlled using the plurality of fences F shown in FIG. 1, for example, by adjusting the number of the plurality of fences F, thereby accurately forming the transmission zeros f1 and fh in a desired band.

That is, the first and second transmission zeros f1 and fh shown in FIG. 6 may be determined in accordance with coupling between the first line signal part LS1 and the fourth line signal part LS4, i.e., the interval between the first line signal part LS1 and the fourth line signal part LS4 and the number of the plurality of fences F. As the intensity of coupling increases, the transmission zeros f1 and fh approach a center frequency fc. As the number of the plurality of fences F increases, the intensity of coupling decreases. That is, as the number of the plurality of fences F increases, negative coupling is reduced, and thus the transmission zeros f1 and fh may move away from the center frequency fc.

As shown in FIG. 1, the reason why the first and fourth line signal parts LS1 and LS4 are formed to be long is that the inductance of each of the first and fourth line signal parts LS1 and LS4 decreases due to negative coupling. On the other hand, because the first and fourth line signal parts LS1 and LS4 are coupled over a large area, insertion loss may be reduced compared to the comparative example.

In addition, as the spacing distances in the first direction between the plate signal parts respectively forming the first to fourth capacitors C1 to C4 shown in FIG. 5 increase, the capacitance of each capacitor may decrease, and the center frequency fc shown in FIG. 6 may shift toward a high frequency. Therefore, according to the embodiment, the center frequency fc of the filter may be varied by adjusting the spacing distances in the first direction between the plate signal parts.

In addition, because the capacitances of the fifth to seventh capacitors C5 to C7 shown in FIG. 5 are coupling amounts, the bandwidth of the filter may decrease as the capacitances thereof decrease. Therefore, according to the embodiment, the bandwidth of the filter may be varied by adjusting the capacitances of the fifth to seventh capacitors C5 to C7.

In addition, in the configuration shown in FIG. 1, if the second line signal part LS2 and the second plate signal part PS2 are not connected to each other via the third connection part CP3, a horizontal coupling structure, rather than a vertical coupling structure, may be formed on the same layer, leading to great increase in loss. However, according to the embodiment, as shown in FIG. 1, since the second line signal part LS2 and the second plate signal part PS2 are connected to each other via the third connection part CP3, loss may be reduced.

In addition, if the parts constituting each layer are disposed in the form shown in FIG. 1, coupling of the inductors may be reduced, which may reduce insertion loss.

While the present disclosure has been particularly shown and described with reference to exemplary embodiments thereof, these embodiments are only proposed for illustrative purposes, and do not restrict the present disclosure, and it will be apparent to those skilled in the art that various changes in form and detail may be made without departing from the essential characteristics of the embodiments set forth herein. For example, respective configurations set forth in the embodiments may be modified and applied. Further, differences in such modifications and applications should be construed as falling within the scope of the present disclosure as defined by the appended claims.

### Mode for Invention

Various embodiments have been described in the best mode for carrying out the disclosure.

### Industrial Applicability

A filter having a stacked structure according to the embodiment may be used in various electronic products.

1. A filter having a stacked structure, the filter comprising:
a plurality of grounds stacked in a first direction, the plurality of grounds having a plate-like shape;
a plate signal part disposed between the plurality of grounds while facing the plurality of grounds in the first direction;
a line signal part disposed adjacent to at least one of the plurality of grounds or the plate signal part in at least one of a second direction or a third direction; and
a plurality of connection parts extending in the first direction to conductively connect at least two of the plurality of grounds, the plate signal part, and the line signal part to each other,
wherein the second direction intersects the first direction, and the third direction intersects each of the first and second directions.

2. The filter according to claim 1, wherein the plurality of grounds includes:
a bottom ground;
a top ground disposed above the bottom ground in the first direction;
a first inserted ground disposed adjacent to the top ground;
a second inserted ground disposed adjacent to the bottom ground;
a first separate ground disposed between the first inserted ground and the second inserted ground in the first direction;
a third inserted ground disposed adjacent to the bottom ground and spaced apart from the second inserted ground in the second direction;
a fourth inserted ground disposed adjacent to the top ground and spaced apart from the first inserted ground in the second direction; and
a second separate ground disposed between the third inserted ground and the fourth inserted ground in the first direction,
wherein the first separate ground is configured to be conductively connected to the first and second inserted grounds, and
wherein the second separate ground is configured to be conductively connected to the third and fourth inserted grounds.

3. The filter according to claim 2, wherein the plate signal part includes:
a first plate signal part spaced apart from each of the first inserted ground and the first separate ground in the first direction and disposed between the first inserted ground and the first separate ground;
a second plate signal part spaced apart from each of the first separate ground and the second inserted ground in the first direction and disposed between the first separate ground and the second inserted ground;
a third plate signal part spaced apart from each of the first plate signal part and the second plate signal part in the first direction and disposed between the first plate signal part and the second plate signal part;
a fourth plate signal part spaced apart from each of the third inserted ground and the second separate ground in the first direction and disposed between the third inserted ground and the second separate ground;
a fifth plate signal part spaced apart from each of the fourth inserted ground and the second separate ground in the first direction and disposed between the fourth inserted ground and the second separate ground; and
a sixth plate signal part spaced apart from each of the fourth plate signal part and the fifth plate signal part in the first direction and disposed between the fourth plate signal part and the fifth plate signal part.

4. The filter according to claim 3, wherein each of the first to sixth plate signal parts is disposed so as to be spaced apart from a ground adjacent thereto in the first direction among the plurality of grounds, with a dielectric interposed therebetween.

5. The filter according to claim 3, wherein the first separate ground has a plane shape spaced apart from the third plate signal part while surrounding the third plate signal part.

6. The filter according to claim 3, wherein the second separate ground has a plane shape spaced apart from the sixth plate signal part while surrounding the sixth plate signal part.

7. The filter according to claim 3, wherein the plurality of connection parts includes:
a first connection part extending in the first direction to connect the first plate signal part and the third plate signal part to each other; and
a second connection part extending in the first direction to connect the fifth plate signal part and the sixth plate signal part to each other.

8. The filter according to claim 3, wherein the line signal part includes:
a first line signal part disposed in a bent line shape extending from the first plate signal part in at least one of the second direction or the third direction;
a second line signal part disposed in a bent line shape extending from a point near the first separate ground in at least one of the second direction or the third direction;
a third line signal part disposed in a bent line shape extending from the fourth plate signal part in at least one of the second direction or the third direction; and
a fourth line signal part disposed in a bent line shape extending from the fifth plate signal part in at least one of the second direction or the third direction.

9. The filter according to claim 8, wherein the plurality of connection parts further includes a third connection part extending in the first direction to connect the second line signal part and the second plate signal part to each other.

10. A filter having a stacked structure, the filter comprising:
a top ground and a bottom ground disposed opposite each other while being vertically spaced apart from each other;
a separate ground disposed between the top ground and the bottom ground;
a plurality of signal parts disposed between the separate ground and each of the top ground and the bottom ground to form a resonator; and
a connection part connecting the separate ground and the plurality of signal parts to each of the top ground and the bottom ground.

11. The filter according to claim 8, wherein the plurality of connection parts comprises:
a fourth connection part extending in the first direction to connect the first inserted ground, the first separate ground, and the second inserted ground to each of the top ground and the bottom ground;
a fifth connection part extending in the first direction to connect the third inserted ground, the second separate ground, and the fourth inserted ground to each of the top ground and the bottom ground;
a sixth connection part connecting the first line signal part to each of the top ground and the bottom ground;
a seventh connection part connecting the second line signal part to each of the top ground and the bottom ground;
an eighth connection part connecting the third line signal part to each of the top ground and the bottom ground; and
a ninth connection part connecting the fourth line signal part to each of the top ground and the bottom ground.

12. The filter according to claim 11, wherein the second inserted ground and the third inserted ground are disposed on a first layer so as to be spaced apart from each other in the second direction,
wherein the second plate signal part, the fourth plate signal part, and the third line signal part are disposed on a second layer located above the first layer in the first direction,
the first and second separate grounds, which are spaced apart from each other in the second direction, the third and sixth plate signal parts, which are spaced apart from each other in the second direction, and the second line signal part are disposed on a third layer located above the second layer in the first direction,
the first and fifth plate signal parts, which are spaced apart from each other in the second direction, and the first and fourth line signal parts are disposed on a fourth layer located above the third layer in the first direction, and
wherein the first inserted ground and the fourth inserted ground are disposed on a fifth layer located above the fourth layer in the first direction so as to be spaced apart from each other in the second direction.

13. The filter according to claim 11, further comprising a plurality of fences having a strip pillar shape extending in the first direction, disposed adjacent to the first and fourth line signal parts, and being configured to conductively connect the top ground and the bottom ground to each other.

14. The filter according to claim 13, wherein the plurality of fences comprises:
a first fence adjacent to the sixth connection part;
a second fence adjacent to the ninth connection part; and
intermediate fences arranged in the second direction while being spaced apart from each other between the first fence and the second fence.

15. The filter according to claim 14, having a transmission zero determined in accordance with a spacing distance between the first line signal part and the fourth line signal part and the number of the plurality of fences.

16. The filter according to claim 14, wherein the first line signal part and the fourth line signal part have plane shapes spaced apart from each other with at least some of the plurality of fences interposed therebetween.

17. The filter according to claim 12, wherein the plurality of grounds, the plate signal part, and the line signal part form a plurality of resonators that are separate from each other,
wherein the plurality of resonators comprises:
a first resonator including the first inserted ground, the first plate signal part, the third plate signal part, the first separate ground, and the first line signal part;
a second resonator including the first separate ground, the second plate signal part, the third plate signal part, the second inserted ground, and the second line signal part;
a third resonator including the second separate ground, the fourth plate signal part, the sixth plate signal part, the third inserted ground, and the third line signal part; and
a fourth resonator including the fourth inserted ground, the fifth plate signal part, the sixth plate signal part, the second separate ground, and the fourth line signal part.

18. The filter according to claim 17, further comprising:
a first input/output port extending and protruding outward from one side of the first line signal part connected to the first plate signal part; and
a second input/output port extending and protruding outward from one side of the fourth line signal part connected to the fifth plate signal part.

19. The filter according to claim 1, further comprising a dielectric in which the plurality of grounds, the plate signal part, the line signal part, and the plurality of connection parts are embedded.

20. An electric product comprising the filter according to claim 1.
